(19) United States
(12) Patent Application Publication
(10) Pub. No.: US 2025/0151452 A1
(43) Pub. Date: May 8, 2025

(54) INTERNALLY SERIES-CONNECTED PEROVSKITE SOLAR CELL MODULES AND PREPARATION METHOD THEREOF

(71) Applicant: QUZHOU MICROQUANTA RENEWABLE ENERGY TECHN. CO., LTD., Quzhou (CN)

(72) Inventors: Jizhong YAO, Quzhou (CN); Buyi YAN, Quzhou (CN); Jiquan ZHU, Quzhou (CN); Wanlei DAI, Quzhou (CN); Yawen YANG, Quzhou (CN)

(73) Assignee: QUZHOU MICROQUANTA RENEWABLE ENERGY TECHN. CO., LTD., Quzhou (CN)

(21) Appl. No.: 19/017,392

(22) Filed: Jan. 10, 2025

Related U.S. Application Data
(63) Continuation-in-part of application No. PCT/CN2024/086163, filed on Apr. 4, 2024.

(30) Foreign Application Priority Data
Apr. 10, 2023 (CN) CN202310410838.7

(51) Int. Cl. H10F 77/20; H10F 19/90; H10F 71/00

(52) U.S. Cl. CPC H10F 77/219; H10F 19/904; H10F 19/908; H10F 71/137; H10F 71/138; H10F 77/215

(57) ABSTRACT

The present disclosure relates to an internally series-connected perovskite solar cell module and a preparation method thereof. The perovskite solar cell module comprises a plurality of sub-cell packs arranged longitudinally. Each sub-cell pack includes a positive electrode tab, a negative electrode tab, and a plurality of cell units arranged horizontally. An internal structure of the positive electrode tab, the negative electrode tab, and the plurality of cell units includes a substrate, a front electrode layer, a light-absorbing layer, and a back electrode layer from bottom to top. The present disclosure allows the back electrode layer to function as a conductor connecting each of the plurality of sub-cell packs through an appropriate laser scribing process, which realizes the series connection effect of the perovskite solar cell module by replacing busbars, thereby greatly avoiding the problem of poor contact when using busbars for series connection.

### CROSS-REFERENCE TO RELATED APPLICATIONS

The present disclosure is a continuation-in-part of international application No. PCT/CN2024/086163, filed on Apr. 4, 2024, which claimed priority to Chinese application No. 202310410838.7, filed on Apr. 10, 2023, the entire contents of each of which are incorporated herein by reference.

### TECHNICAL FIELD

The present disclosure relates to the technical field of solar cell structure and preparation, and in particular, relates to an internal series-connected perovskite solar cell module and a preparation method thereof.

### BACKGROUND

An internally series-connected perovskite solar cell module is an innovative photovoltaic technology that achieves high-efficiency photoelectric conversion and good spectral response by applying perovskite solar cell materials in a multi-layer structure. A connection of the internally series-connected perovskite solar cell module typically requires the use of busbars. However, the busbars present certain drawbacks, mainly in the following aspects: 1) during an encapsulation process, placing the busbars can easily scratch a back electrode layer, potentially causing localized short circuits, which leads to a significant decrease in cell efficiency; 2) the introduction of busbars can also exacerbate an uneven stress distribution between a substrate and a backplane, reducing an overall strength of the module and weakening its impact resistance; and 3) from a cost perspective, the internally series-connected modules requires a larger number of busbars, increasing the probability of poor contact between the busbars and the back electrode layer.

Therefore, there is a need to provide an internally series-connected perovskite solar cell module and a preparation method thereof, which can achieve the series connection effect of the perovskite solar cell module, replacing the traditional busbar, thus enabling an internal series connection between sub-cell packs of the perovskite solar cell module without using a busbar.

### SUMMARY

The technical problem to be solved by the present disclosure is to provide an internally series-connected perovskite solar cell module and a preparation method thereof. Based on existing process technologies, a complete perovskite solar cell module is divided into several identical cell units by cutting. Through an appropriate laser scribing process, a back electrode layer of the perovskite solar cell module is used as a conductor to connect the cell units, thereby achieving a series connection effect for the perovskite solar cell module and replacing traditional busbars.

One or more embodiments of the present disclosure provide an internally same-side series-connected perovskite solar cell module. The internally same-side series-connected perovskite solar cell module may comprise a plurality of sub-cell packs arranged longitudinally, and positions of positive polarities and negative polarities of two adjacent sub-cell packs may be reversed. Each sub-cell pack may include a positive electrode tab, a negative electrode tab, and a plurality of cell units that are arranged horizontally, the positive electrode tab and the negative electrode tab may be located at a front side and a rear side of each sub-cell pack, respectively, the plurality of cell units may be located between the positive electrode tab and the negative electrode tab. Negative electrode tabs and positive electrode tabs between the two adjacent sub-cell packs are electrically connected only through an intermediate connection strap, respectively, and remaining portions between the two adjacent sub-cell packs may be insulated from each other through an intermediate insulation strap. An internal structure of the positive electrode tab, the negative electrode tab, and the plurality of cell units may include a substrate, a front electrode layer, a light-absorbing layer, and a back electrode layer from bottom to top. Two adjacent cell units, the cell unit and the positive electrode tab, and the cell unit and the negative electrode tab, may be respectively separated into sub-cell packs with an internal conductive connection by a scribing line group composed of a line P1, a line P2, and a line P3. The P1 line may scribe off the front electrode layer, the substrate at a bottom of a groove formed by the P1 line may be exposed, the P2 line may be close to the P1 line in a same group and may scribe off the light-absorbing layer, the front electrode layer at a bottom of a groove formed by the P2 line may be exposed, and the groove formed by the P2 line may be filled with an electrically-conductive material. The P3 line may be close to the P2 line in a same group and may scribe off the back electrode layer and the light-absorbing layer at the same time, and the front electrode layer at a bottom of a groove formed by the P3 line may be exposed. A positive electrode busbar may be conductively laid on a surface of a back electrode layer of a positive electrode tab of a leftmost sub-cell pack, and a negative electrode busbar may be conductively laid on a surface of a back electrode layer of a negative electrode tab of a rightmost sub-cell pack, and the positive electrode busbar and the negative electrode busbar may be both located on a same side of the perovskite solar cell module.

One or more embodiments of the present disclosure provide an internally opposite-side series-connected perovskite solar cell module. The internally opposite-side series-connected perovskite solar cell module may comprise a plurality of sub-cell packs arranged horizontally, and positions of positive polarities and negative polarities of two adjacent sub-cell packs may be the same. Each sub-cell pack may include a positive electrode tab, a negative electrode tab, and a plurality of cell units that are arranged horizontally, the positive electrode tab and the negative electrode tab are located at a front side and a rear side of each sub-cell pack, respectively, the plurality of cell units are located between the positive electrode tab and the negative electrode tab. Negative electrode tabs and positive electrode tabs between two adjacent sub-cell packs may be electrically connected only through a series connection strap, respectively, insulation grooves and sub-cell packs adjacent to the insulation grooves are arranged on two sides of the series connection strap, respectively, and the insulations grooves and the sub-cell packs adjacent to the insulation grooves are insulated from each other. An internal structure of the positive electrode tab, the negative electrode tab, and the plurality of cell units may include a substrate, a front electrode layer, a light-absorbing layer, and a back electrode layer from bottom to top. Two adjacent cell units, the cell unit and the positive electrode tab, and the cell unit and the negative electrode tab, may be respectively separated into sub-cell packs with an internal conductive connection by a scribing line group composed of a line P1, a line P2, and a line P3. The P1 line may scribe off the front electrode layer, the substrate at a bottom of a groove formed by the P1 line may be exposed, the P2 line may be close to the P1 line in a same group and may scribe off the light-absorbing layer, the front electrode layer at a bottom of a groove formed by the P2 line may be exposed, and the groove formed by the P2 line may be filled with an electrically-conductive material. The P3 line may be close to the P2 line in the same group and may scribe off the back electrode layer and the light-absorbing layer at the same time, and the front electrode layer at a bottom of a groove formed by the P3 line may be exposed. A positive electrode busbar may be conductively laid on a surface of a back electrode layer of a positive electrode tab of a leftmost sub-cell pack, and a negative electrode busbar may be conductively laid on a surface of a back electrode layer of a negative electrode tab of a rightmost sub-cell pack, and the positive electrode busbar and the negative electrode busbar may be both located on a front side and a rear side of the perovskite solar cell module, respectively.

One or more embodiments of the present disclosure provide an internally series-connected perovskite solar cell module. The internally series-connected perovskite solar cell module may comprise the internally same-side series-connected perovskite solar cell module and the internally opposite-side series-connected perovskite solar cell module.

One or more embodiments of the present disclosure provide a method for preparing an internally same-side series-connected perovskite solar cell module. The method may comprise: preparing the front electrode layer on the substrate, scribing the P1 line at a position of each cell unit on the front electrode layer, the P1 line scribing off the front electrode layer, and exposing the substrate at the bottom of the groove formed by the P1 line; laying the light-absorbing layer on the front electrode layer and in the groove formed by the P1 line, scribing the P2 line on the light-absorbing layer close to the P1 line, and the P2 line scribing off the light-absorbing layer and exposing the front electrode layer at the bottom of the groove formed by the P2 line; laying the back electrode layer on the light-absorbing layer and in the groove formed by the P2 line, scribing the P3 line on the back electrode layer close to the P2 line, and the P3 line scribing off the back electrode layer and light-absorbing layer, exposing the front electrode layer at the bottom of the groove formed by the P3 line, and obtaining the sub-cell pack composed of a positive electrode tab, a negative electrode tab, and a plurality of cell units that are arranged horizontally; scribing the P4 line at a position of the intermediate insulation strap on the back electrode layer, and the P4 line exposing the substrate at a bottom of the intermediate insulation strap, and retaining a position of the intermediate connection strap on the back electrode layer; isolating edges around a region where the sub-cell pack is located to expose the substrate at a bottom of an isolated region, and obtaining a plurality of sub-cell packs that are arranged horizontally and sequentially series-connected through the intermediate connection strap, with positions of positive electrode tabs and negative electrode tabs of two adjacent sub-cell packs being reversed; and conductively laying the positive electrode busbar on the surface of the back electrode layer of the positive electrode tab of the leftmost sub-cell pack, and conductively laying the negative electrode busbar on the surface of the back electrode layer of the negative electrode tab of the rightmost sub-cell pack, and the positive electrode busbar and the negative electrode busbar being both located on the same side of the perovskite solar cell module.

One or more embodiments of the present disclosure provide a method for preparing an internally opposite-side series-connected perovskite solar cell module. The method may comprise: preparing the front electrode layer on the substrate, scribing the P1 line at a position of each cell unit on the front electrode layer, the P1 line scribing off the front electrode layer and exposing the substrate at the bottom of the groove formed by the P1 line; laying the light-absorbing layer on the front electrode layer and in the groove formed by the P1 line, scribing the P2 line at a position of the light-absorbing layer close to the P1 line, and the P2 line scribing off the light-absorbing layer and exposing the front electrode layer at the bottom of the groove formed by the P2 line; laying the back electrode layer on the light-absorbing layer and in the groove formed by the P2 line, scribing the P3 line at a position of the back electrode layer close to the P2 line, and the P3 line scribing off the back electrode layer and light-absorbing layer, exposing the front electrode layer at the bottom of the groove formed by the P3 line, and obtaining the sub-cell pack composed of a positive electrode tab, a negative electrode tab, and a plurality of cell units that are arranged horizontally; scribing a P4 line at a position of the insulation groove on the back electrode layer, and the P4 line exposing the substrate at a bottom of the insulation groove and retaining a position of the series connection strap on the back electrode layer; isolating edges around a region where the sub-cell pack is located to expose the substrate at a bottom of an isolated region, and obtaining a plurality of sub-cell packs that are arranged horizontally and sequentially series-connected through the series connection strap, with positions of positive polarities and negative polarities of two adjacent sub-cell packs being same; and conductively laying the positive electrode busbar on the surface of the back electrode layer of the positive electrode tab of the leftmost sub-cell pack, and conductively laying the negative electrode busbar on the surface of the back electrode layer of the negative electrode tab of the rightmost sub-cell pack, and the positive electrode busbar and the negative electrode busbar being both located on the front side and the rear side of the perovskite solar cell module, respectively.

One or more embodiments of the present disclosure provide a method for preparing an internally series-connected perovskite solar cell module. The method may comprise: preparing the front electrode layer on the substrate, scribing the P1 line at the position of each cell unit on the front electrode layer, the P1 line scribing off the front electrode layer and exposing the substrate at the bottom of the groove formed by the P1 line; laying the light-absorbing layer on the front electrode layer and in the groove formed by the P1 line, scribing the P2 line on the light-absorbing layer close to the P1 line, and the P2 line scribing off the light-absorbing layer and exposing the front electrode layer at the bottom of the groove formed by the P2 line; laying the back electrode layer on the light-absorbing layer and in the groove formed by the P2 line, scribing the P3 line on the back electrode layer close to the P2 line, the P3 line scribing off the back electrode layer and light-absorbing layer exposing the front electrode layer at the bottom of the groove formed by the P3 line, and obtaining the sub-cell pack composed of a positive electrode tab, a negative electrode tab, and a plurality of cell units that are arranged horizontally; dividing the back electrode layer into a region of internally same-side series-connected perovskite solar cell module and a region of internally opposite-side series-connected perovskite solar cell module, scribing a P4 line at a position of an intermediate insulation strap on a back electrode layer in the region of internally same-side series-connected perovskite solar cell module, and the P4 line exposing the substrate at a bottom of the intermediate insulation strap, and retaining a position of the intermediate connection strap on the back electrode layer; isolating edges around a region where the sub-cell pack is located, an isolated region exposing the substrate at the bottom, and obtaining a plurality of sub-cell packs that are arranged horizontally and sequentially series-connected through the intermediate connection strap, with positions of positive polarities and negative polarities of two adjacent sub-cell packs being reversed; scribing a P4′ line at a position of an insulation groove on a back electrode layer in the region of internally opposite-side series-connected perovskite solar cell module, the P4′ line exposing the substrate at a bottom of the insulation groove, and retaining a position of the series connection strap on the back electrode layer; isolating edges around a region where the sub-cell pack is located to expose the substrate at a bottom of an isolated region, and obtaining a plurality of sub-cell packs that are arranged horizontally and sequentially series-connected through the series connection strap, with positions of positive polarities and negative polarities of two adjacent sub-cell packs being same; and connecting a prepared internally same-side series-connected perovskite solar cell module and a prepared internally opposite-side series-connected perovskite solar cell module as needed, and conductively laying the positive electrode busbar on a surface of a back electrode layer of a positive electrode tab of one of the sub-cell pack, and conductively laying the negative electrode busbar on a surface of a back electrode layer of a negative electrode tab of another sub-cell pack.

In embodiments of the present disclosure, the perovskite solar cell module may comprise a plurality of sub-cell packs arranged longitudinally. Each sub-cell pack may include a positive electrode tab, a negative electrode tab, and a plurality of cell units arranged horizontally. The internal structure of the positive electrode tab, the negative electrode tab, and the plurality of cell units may include a substrate, a front electrode layer, a light-absorbing layer, and a back electrode layer from bottom to top. The present disclosure utilizes an appropriate laser scribing process to enable the back electrode layer to function as a conductor connecting the sub-cell packs, thereby achieving the series connection of the perovskite solar cell module. This approach replaces traditional busbars, allowing for internal series connection between the sub-cell packs of the perovskite solar cell module without the need for busbars, thereby avoiding issues such as scratching the thin film of the back electrode layer during encapsulation when realizing series connection through busbars, or even leading to internal short circuits within the perovskite solar cell module and reducing its power generation efficiency. At the same time, by utilizing the back electrode layer as a thin-film conductor to replace busbars for the connection between sub-cell packs in the perovskite solar cell module, the use of busbars is greatly reduced, effectively avoiding contact issues associated with series connections based on busbars. Furthermore, this method can be extended further to connect multiple small modules in series on the same module. Depending on the specific dimensions and arrangement, the series connection method described in the present disclosure can be applied. In certain specialized scenarios where there are requirements for the area and voltage of solar cells, the internal series connection within the module can effectively satisfy these demands, thereby opening up new market opportunities for the application of perovskite solar thin-film cells.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure, where:

FIG. 1 is a schematic diagram illustrating an exemplary plan view of an internally same-side series-connected perovskite solar cell module according to some embodiments of the present disclosure;

FIG. 2 is a schematic diagram illustrating an exemplary plan view of an internally opposite-side series-connected perovskite solar cell module according to some embodiments of the present disclosure;

FIG. 3 is a schematic diagram illustrating a rotational section view in FIG. 1 along P-P according to some embodiments of the present disclosure;

FIG. 4 is a schematic diagram illustrating an enlarged view of a region M in FIG. 1 according to some embodiments of the present disclosure;

FIG. 5 is a schematic diagram illustrating an enlarged view of a region N in FIG. 2 according to some embodiments of the present disclosure;

FIG. 6 is a flowchart illustrating a process for preparing an internally same-side series-connected perovskite solar cell module according to some embodiments of the present disclosure;

FIG. 7 is a schematic diagram illustrating a P1 line according to some embodiments of the present disclosure;

FIG. 8 is a schematic diagram illustrating a P2 line according to some embodiments of the present disclosure;

FIG. 9 is a schematic diagram illustrating a P3 line according to some embodiments of the present disclosure;

FIG. 10 is a flowchart illustrating a process for preparing an internally opposite-side series-connected perovskite solar cell module according to some embodiments of the present disclosure;

FIG. 11 is a schematic diagram illustrating a series connection strap and insulation groove according to some embodiments of the present disclosure;

FIG. 12 is a flowchart illustrating a process for preparing an internally series-connected perovskite solar cell module according to some embodiments of the present disclosure;

FIG. 13 is a schematic diagram illustrating a system for preparing a perovskite solar cell module according to some embodiments of the present disclosure; and

FIG. 14 is a schematic diagram illustrating an edge isolation operation according to some embodiments of the present disclosure.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system”, “device”, “unit,” and/or “module” as used herein is a method for distinguishing between different components, elements, parts, sections, or assemblies at different levels. However, the words may be replaced by other expressions if other words accomplish the same purpose.

As shown in the present disclosure and the claims, unless the context clearly suggests an exception, the words “a”, “an”, “one kind”, and/or “the” do not refer specifically to the singular, but may also include the plural. Generally, the terms “including” and “comprising” suggest only the inclusion of clearly identified steps and elements that do not constitute an exclusive list, and the method or apparatus may also include other steps or elements.

Flowcharts are used in the present disclosure to illustrate operations performed by a system in accordance with embodiments of the present disclosure. It should be appreciated that the preceding or following operations are not necessarily performed in an exact sequence. Instead, steps can be processed in reverse order or simultaneously. Also, it is possible to add other operations to these processes or remove a step or steps from them.

In order to make the technical problems, technical solutions, and beneficial effects solved in the present disclosure clearer and more understandable, the following content is described in further detail in combination with the accompanying drawings and embodiments. It should be understood that the specific embodiments described herein are only for explaining the present disclosure, and are not intended to limit the present disclosure.

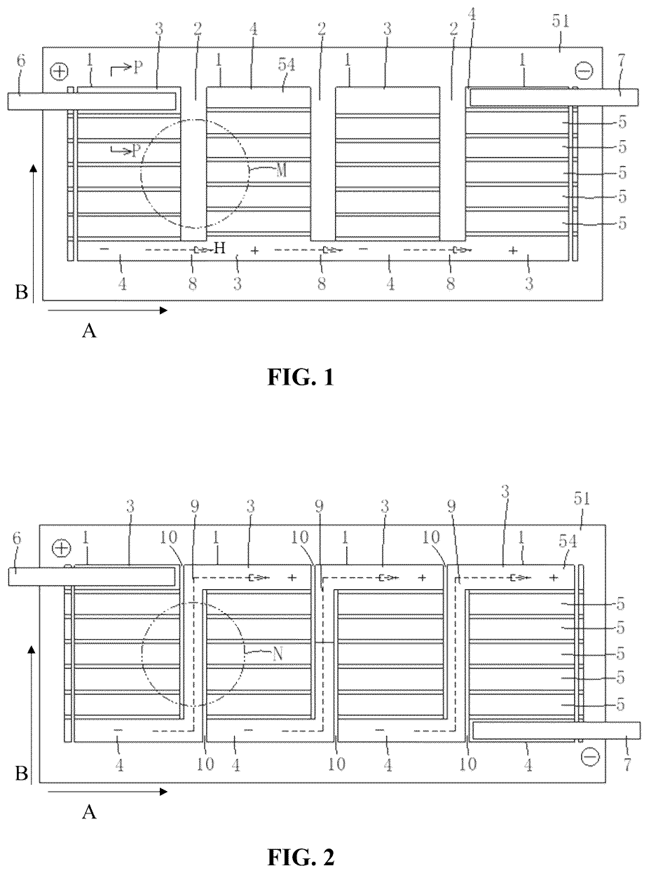

FIG. 1 is a schematic diagram illustrating an exemplary plan view of an internally same-side series-connected perovskite solar cell module according to some embodiments of the present disclosure.

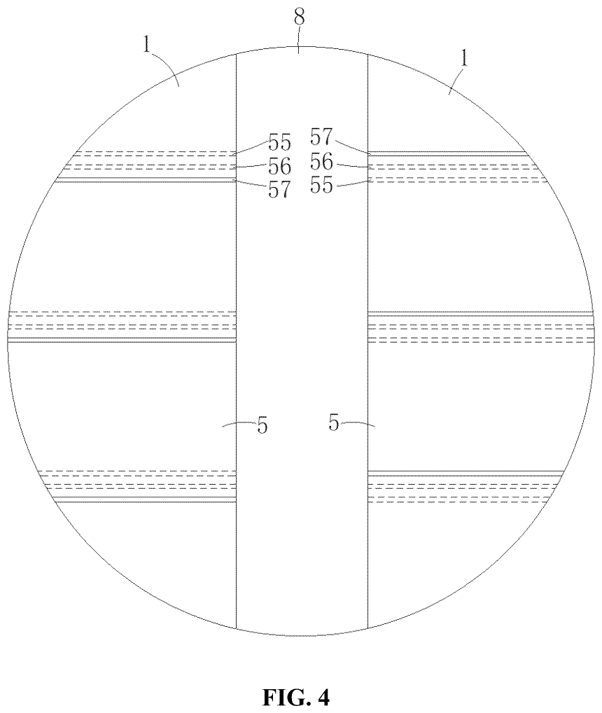

As shown in FIG. 1, FIG. 3, and FIG. 4, in some embodiments, the internally same-side series-connected perovskite solar cell module may comprise a plurality of sub-cells packs 1 arranged longitudinally, and positions of positive polarities and negative polarities of two adjacent sub-cell packs 1 may be reversed. A longitudinal direction is a direction pointed to by an arrow A in FIG. 1 and a horizontal direction is a direction pointed to by an arrow B in FIG. 1.

A sub-cell pack may be an individual unit of the solar cell module, which is a combination of solar cells having a particular structure. In some embodiments, a count of sub-cell packs arranged longitudinally in the solar cell module may be 2, 3, 4, 5, 8, 10, or the like.

In some embodiments, as shown in FIG. 1, each sub-cell pack 1 includes a positive electrode tab 3, a negative electrode tab 4, and a plurality of cell units 5 arranged horizontally. The positive electrode tab 3, the negative electrode tab 4, and the plurality of cell units 5 are internally series-connected to form the sub-cell pack 1.

A positive electrode tab and a negative electrode tab may be critical electrical connection points in the solar cell module, and may be configured to output current from a sub-cell pack to a load or storage device. The positive electrode tab may be configured to output current from the sub-cell pack to a positive terminal of the load or storage device, and the negative electrode tab may be configured to output current from the sub-cell pack to a negative terminal of the load or storage device.

A cell unit may be a basic unit or unit cell in a solar module configured to convert light energy into electrical energy. In some embodiments, a count of cell units in each sub-cell pack is 2, 3, 4, 5, 8, 10, or the like.

In some embodiments, as shown in FIG. 1, the positive electrode tab 3 and the negative electrode tab 4 are located at a front side and rear side (i.e., ends along a horizontal direction) of each sub-cell pack 1, respectively, and a plurality of cell units 5 are located between the positive terminal tab 3 and the negative terminal tab 4. The negative electrode tab 4 and the positive electrode tab 3 between two adjacent sub-cell packs 1 are electrically connected only through an intermediate connection strap 8, respectively, and remaining portions between the two adjacent sub-cell packs 1 may be insulated from each other through an intermediate insulation strap 2. A dashed line with an arrow H in FIG. 1 denotes a conduction direction of electrons within the perovskite solar cell module.

The intermediate connection strap may be an electrically conductive strap within the solar cell module that makes connections and conducts current. The intermediate connection strap may be configured to make an electrical connection between two adjacent sub-cell packs to ensure that current can be efficiently transferred between sub-cell packs and ultimately output to enable a plurality of sub-cell packs to form a complete solar cell module. In some embodiments, the intermediate connection strap may be made of a highly conductive material, such as copper.

The intermediate insulation strap may be a portion of the solar cell module that provides insulation protection. The intermediate insulation strap may prevent current from flowing along unintended paths, thereby avoiding short circuits and preventing efficiency loss or component failure due to improper connections. In some embodiments, the intermediate insulation strap is made of a material with good insulating properties, such as one or a combination of polyester, Polytetrafluoroethylene (PTFE), or other polymers resistant to high temperatures, chemicals, or the like.

FIG. 4 is a schematic diagram illustrating an enlarged view of a region M in FIG. 1 according to some embodiments of the present disclosure. As can be seen in FIG. 4, two adjacent sub-cell packs 1 may be connected to each other through the intermediate connection strap 8, and each sub-cell pack 1 may include a plurality of cell units 5.

FIG. 3 is a schematic diagram illustrating a rotational section view in FIG. 1 along P-P. The rotational sectional view along P-P is a sectional view obtained by rotating P points indicated by two arrows in FIG. 1 along a direction indicated by the arrows.

In some embodiments, as shown in FIG. 3, an internal structure of the plurality of cell units 5 includes a substrate 51, a front electrode layer 52, a light-absorbing layer 53, and a back electrode layer 54 from bottom to top (in a direction indicated by an arrow C in FIG. 3). The positive electrode tab 3 may be arranged above the back electrode layer 54 (i.e., an ending end of the arrow C).

The substrate may be a mechanical support in a cell unit. The substrate may be a base layer of the cell unit and carry all other functional layers. Therefore, the substrate needs to be mechanically strong enough, while providing light transmission and electrical conduction where necessary. In some embodiments, the substrate is made of glass, plastic, stainless steel, or the like.

The front electrode layer may be an electrical contact surface in the cell unit. The front electrode layer may be configured to collect and conduct electrical current generated from the light-absorbing layer while blocking as little light as possible. In some embodiments, the front electrode layer is made of a material such as transparent conductive oxide (TCO), e.g., indium tin oxide (ITO) or fluorine-doped tin oxide (FTO), to ensure conductive and light transmissive properties.

The light-absorbing layer may be a functional layer in the cell unit that absorbs photons and generates electrons. In some embodiments, the light-absorbing layer is made of perovskite material.

The back electrode layer is another electrical contact surface in the cell unit. The back electrode layer is configured to cooperate with the front electrode layer to collect and conduct current to form a closed-loop circuit. In some embodiments, the back electrode layer is made of aluminum, silver, or other conductive metallic material.

In some embodiments, as shown in FIG. 3, two adjacent cell units 5, and the cell unit 5 and the positive electrode tab 3, and the cell unit 5 and the negative electrode tab 4, are respectively separated into the sub-cell pack 1 with an internal conductive connection by a scribing line group composed of a line P1 55, a line P2 56, and a line P3 57.

Scribing refers to a precise cutting of solar cell materials to achieve a specific electrical function and structural layout. Through the scribing, an electrically isolated environment can be created, dimensions of cells can be defined, current paths can be optimized, and component efficiency can be improved. In some embodiments, scribing can be achieved by laser scribing.

The P1 line 55 may scribe off the front electrode layer 52, and the substrate 58 at a bottom of a groove formed by the P1 line 55 may be exposed. The P2 line 56 may be close to the P1 line 55 in a same group and may scribe off the light-absorbing layer 53, and the front electrode layer 52 at a bottom of a groove formed by the P2 line may be exposed, and the groove formed by the P2 line 56 may be filled with an electrically-conductive material. The P3 line 57 may be close to the P2 line 56 and may scribe off both the back electrode layer 54 and the light-absorbing layer 53, and the front electrode layer 52 at a bottom of a groove formed by the P3 line 57 may be exposed.

The P1 line may create an electrically isolated environment as a basis for each individual cell unit. The P2 line, which is scribed on the light-absorbing layer, can ensure that an effective current path of the cell unit is well-defined, and the electrically conductive material filled in the groove can reduce series resistance between cell units. The P3 line can enable a connection of electrical structures to regulate output voltage and current. In some embodiments, the electrically conductive material filled in the groove formed by the P2 line includes a conductive paste, conductive ink, metal coating, or the like.

A dotted line with an arrow in FIG. 3 denotes a conduction direction of electrons within the perovskite solar cell module. As indicated by the dotted line with the arrow in FIG. 3, an electron may pass in turn through the positive electrode tab 3, the back electrode layer 54, the P2 line 56, the front electrode layer 52, the light-absorbing layer 53, the back electrode layer 54, the P2 line 56, the front electrode layer 52, the light-absorbing layer 53, the back electrode layer 54, and the negative electrode tab 4 for conduction.

In some embodiments, as shown in FIG. 1, a positive electrode busbar 6 is conductively laid on a surface of the back electrode layer 54 of the positive electrode tab 3 of the leftmost sub-cell pack 1 at a starting end (i.e., a starting end of an arrow A), and a negative electrode busbar 7 is conductively laid on a surface of the back electrode layer 54 of the negative electrode tab 4 of the rightmost sub-cell pack 1 at an ending end (i.e., an ending end of the arrow A).

The busbar may be a portion of the solar module that plays a key role in conducting current. In some embodiments, the busbar may be made of a highly conductive metal (e.g., copper or silver) coated with a thin layer of tin or nickel plating to enhance conductivity and anti-corrosion properties.

In some embodiments, the positive electrode busbar 6 and the negative electrode busbar 7 are both located on a same side of the perovskite solar cell module, such as a side where an ending end of an arrow B is located. The positive electrode busbar 6 and the negative electrode bus 7 may be electrically connected to the back electrode layer 54 of the negative electrode tab 4 and the back electrode layer 54 of the positive electrode tab 3, respectively, of the sub-cell pack 1 in which they are located.

As a result, a plurality of sub-cell packs can be series-connected through a positive electrode busbar and a negative electrode busbar on a same side to form the internally same-side series-connected perovskite solar cell module. The positive electrode busbar and the negative electrode busbar can collect and conduct currents from the plurality of sub-cell packs, pooling outputs of the plurality of sub-cell packs, for electrical connection and power output of the cell module.

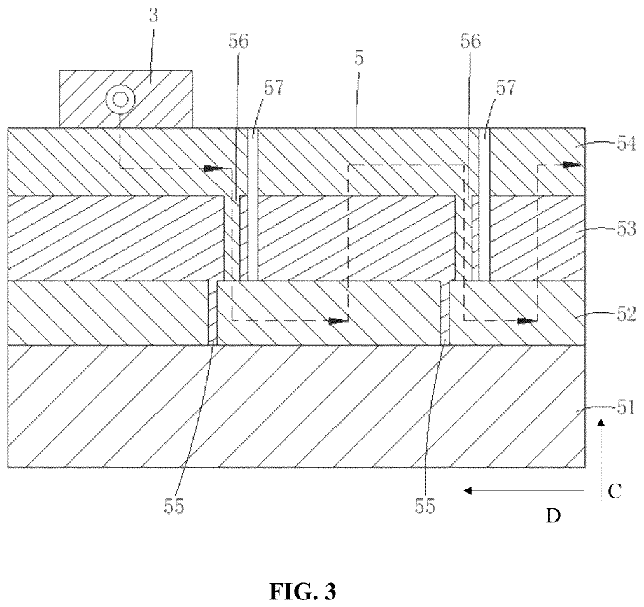

FIG. 2 is a schematic diagram illustrating an exemplary plan view of an internally opposite-side series-connected perovskite solar cell module according to some embodiments of the present disclosure;

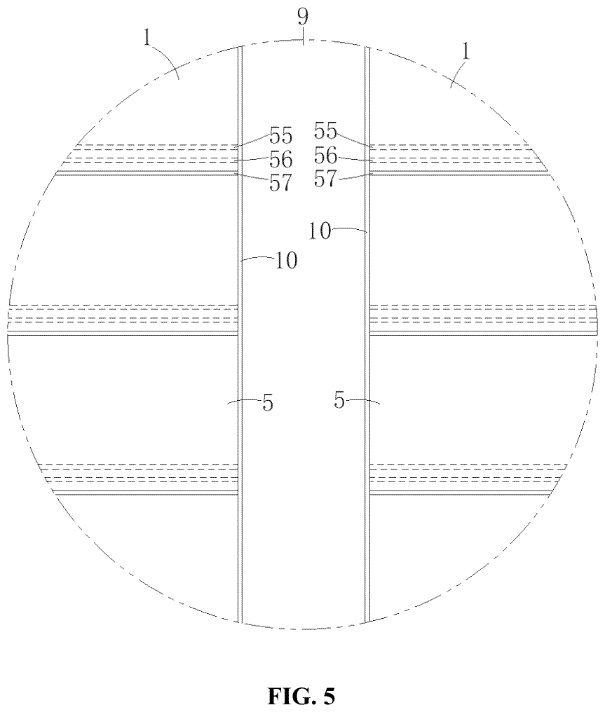

As shown in FIG. 2, FIG. 3, and FIG. 5, in some embodiments, an internally opposite-side series-connected perovskite solar cell module comprises a plurality of sub-cell packs 1 arranged horizontally, and positions of positive polarities and negative polarities of two adjacent sub-cell packs 1 are the same. A longitudinal direction denotes a direction pointed to by an arrow A in FIG. 2, and a horizontal direction denotes a direction pointed to by an arrow B in FIG. 2.

In some embodiments, as shown in FIG. 2, each sub-cell pack 1 includes a positive electrode tab 3, a negative electrode tab 4, and a plurality of cell units 5 arranged horizontally. The positive electrode tab 3, the negative electrode tab 4, and the plurality of cell units 5 are internally series-connected to form the sub-cell pack 1. In some embodiments, the positive electrode tab 3 and the negative electrode tab 4 are located at a front side and rear side of each sub-cell pack 1, respectively, and the plurality of cell units 5 are located between the positive electrode tab 3 and the negative electrode tab 4.

In some embodiments, negative electrode tabs 4 and positive electrode tabs 3 between two adjacent sub-cell packs 1 are electrically connected only through a series connection strap 9, and insulation grooves 10 and sub-cell packs 1 that are insulated from insulation grooves are arranged on two sides of the series connection strap 9, respectively, and an insulation groove and a sub-cell pack that is adjacent to the insulation grooves are insulated from each. A dotted line with an arrow in FIG. 2 denotes a conduction direction of electrons within the perovskite solar cell module.

The series connection strap may be an electrically conductive strap in an interior of the solar module that makes connections and conducts current. The series connection strap may be configured to electrically connect positive electrodes and negative electrodes of a plurality of sub-cell packs. The insulation groove may be a recess within the solar cell module that achieves electrical isolation. Coordination of the series connection strap and the insulation groove ensures that a current flows along a preset path, realizing an effective current output for the entire cell module.

As shown in FIG. 2, an insulation groove is arranged at a left side (a side opposite to a direction indicated by the arrow A) of the series connection strap between two adjacent sub-cell packs, and an insulation groove is arranged at a right side (a side in a same direction as indicated by the arrow A) of the series connection strap. A portion below a negative electrode tab (a side opposite to a direction indicated by the arrow B) of the former sub-cell pack is not provided with an insulation groove, and a portion above a positive electrode tab of a latter sub-cell pack (a side in a same direction as indicated by the arrow B) is not provided with an insulation groove. In this way, this allows a current flowing out of a previous sub-cell pack to pass through a negative electrode tab and a series connection busbar, and then flow into a positive electrode tab of a next sub-cell pack, preventing short circuits or unnecessary current leakage.

FIG. 5 is a schematic diagram illustrating an enlarged view of a region N in FIG. 2 according to some embodiments of the present disclosure. As can be seen in FIG. 5, two adjacent sub-cell packs 1 may be connected to each other through the series connection strap 9, and each sub-cell pack 1 may include a plurality of cell units 5.

In some embodiments, an internal structure of the positive electrode tab 3, the negative electrode tab 4, and the plurality of cell units 5 includes the substrate 51, the front electrode layer 52, the light-absorbing layer 53, and the back electrode layer 54 from bottom to up. Two adjacent cell units 5, the cell unit 5 and the positive electrode tab 3, and the cell unit 5 and the negative electrode tab 4, are respectively separated into sub-cell packs 1 with an internal conductive connection by a scribing line group composed of the line P1 55, the line P2 56, and the line P3 57. The P1 line 55 may scribe off the front electrode layer 52, and the substrate 51 at a bottom of a groove formed by the P1 line 55 may be exposed. The P2 line 56 may be close to the P1 line 55 in a same group and may scribe off the light-absorbing layer 53, and the front electrode layer 56 at a bottom of a groove formed by the P2 line 56 may be exposed, and the groove formed by the P2 line 56 may be filled with an electrically-conductive material. The P3 line 57 may be close to the P2 line 56 in a same group and may scribe off both the back electrode layer 54 and the light-absorbing layer 53, and the front electrode layer 52 at a bottom of a groove formed by the P3 line 57 may be exposed.

An internal structure of the cell unit is similar to that of the cell unit described in FIG. 1 and FIG. 3, and more descriptions of the cell unit and the sub-cell pack can be found in FIG. 1 and its related descriptions.

In some embodiments, the positive electrode busbar 6 is conductively laid on a surface of the back electrode layer 54 of the positive electrode tab 3 of the leftmost sub-cell pack 1 at a starting end (i.e., a starting end of the arrow A), and a negative electrode busbar 7 is conductively laid on a surface of the back electrode layer 54 of the negative electrode tab 4 of the rightmost sub-cell pack 1 at an ending end (i.e., an ending end of the arrow A). In some embodiments, the positive electrode busbar 6 and the negative electrode busbar 7 are both located on a front side and rear side (i.e., two ends along a horizontal direction) of the perovskite solar cell module, respectively. The positive electrode busbar 6 and the negative electrode busbar 7 are electrically connected to the back electrode layer 54 of the positive electrode tab 3 and the back electrode layer 54 of the negative electrode tab 4, respectively, of a sub-cell pack 1 in which they are located.

As a result, a plurality of sub-cell packs may be series-connected through a positive electrode busbar and a negative electrode busbar at a front side and rear side, a series connection strap, and an insulation groove to form an internally opposite-side series-connected perovskite solar cell module. The positive electrode busbar and the negative electrode busbar can collect and conduct the current from the sub-cell packs, pooling the outputs of multiple sub-cell packs to achieve electrical connection and power output for the cell module.

Some embodiments of the present disclosure further provide an internally series-connected perovskite solar cell module. An interior of the internally series-connected perovskite solar cell module includes the internally same-side series-connected perovskite solar cell module and the internally opposite-side series-connected perovskite solar cell module according to any embodiments of the present disclosure.

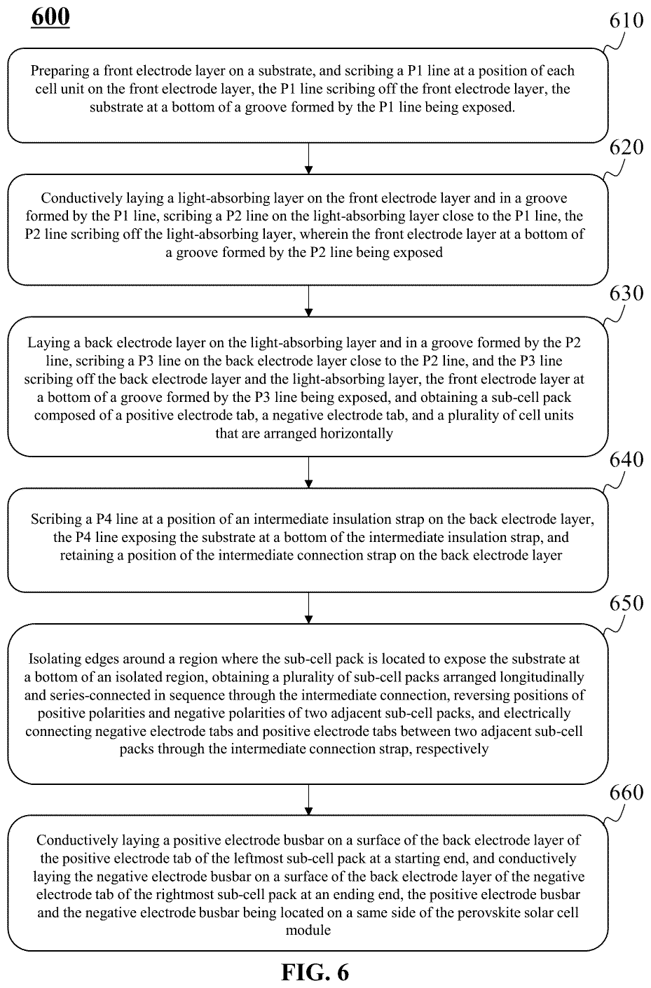

FIG. 6 is a flowchart illustrating a process for preparing an internally same-side series-connected perovskite solar cell module according to some embodiments of the present disclosure. In some embodiments, a process 600 may be performed manually or by a system for preparing a perovskite solar cell module.

As shown in FIG. 6, the process 600 includes following operations.

In 610, a front electrode layer may be prepared on a substrate, and a P1 line may be scribed at a position of each cell unit on the front electrode layer. The P1 line may scribe off the front electrode layer, and the substrate at a bottom of a groove formed by the P1 line may be exposed.

More descriptions of the front electrode layer, the cell unit, the substrate, and the P1 line can be found in FIG. 1 and the related descriptions thereof. The substrate and the front electrode layer need to be prepared before scribing.

In some embodiments, the substrate is made of materials such as glass, plastic, or stainless steel. The substrate needs to be sufficiently mechanically strong while providing light transmittance and electrical conductivity where necessary.

In some embodiments, the front electrode layer is made of a material such as transparent conductive oxide (TCO), e.g., indium tin oxide (ITO) or fluorine-doped tin oxide (FTO), or the like. In some embodiments, the substrate is prepared first, and then the front electrode layer is prepared on a prepared substrate. In some embodiments, the front electrode layer is prepared using sputtering deposition, chemical vapor deposition (CVD), or sol-gel manner.

In some embodiments, the P1 line is achieved by laser scribing. Scribing the P1 line on the front electrode layer can result in electrical isolation between different cell units.

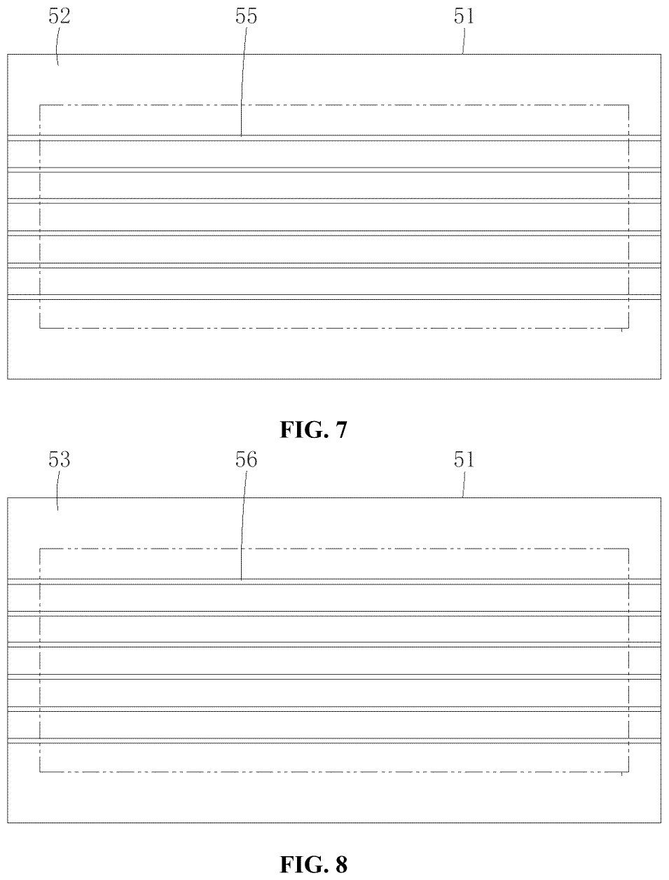

FIG. 7 is a schematic diagram illustrating a P1 line according to some embodiments of the present disclosure. A double dotted line in FIG. 7 denotes a location where the sub-cell pack 1 of a perovskite solar cell module is located. As shown in FIG. 7, scribing the P1 line 55 on the front electrode layer 52 may form a groove formed by the P1 line, and the substrate at the bottom of the groove formed by the P1 line may be exposed. A plurality of P1 lines 55 may be scribed at different positions of the sub-cell pack 1 to form a plurality of grooves formed by the P1 lines. A position of the P1 line may be viewed essentially as a position for dividing a plurality of cell units.

In 620, a light-absorbing layer may be conductively laid on the front electrode layer and in the groove formed by the P1 line. A P2 line may be scribed on the light-absorbing layer close to the P1 line. The P2 line may scribe off the light-absorbing layer, and the front electrode layer at a bottom of a groove formed by the P2 line may be exposed.

More descriptions of the light-absorbing layer and the P2 line can be found in FIG. 1 and the related descriptions thereof.

The light-absorbing layer may be laid on a surface of the front electrode layer and in the groove formed by the P1 line, i.e., the light-absorbing layer in the groove formed by the P1 line may contact the substrate at the bottom of the groove formed by the P1 line. In some embodiments, a manner for laying the light-absorbing layer includes one or a combination of chemical vapor deposition (CVD), physical vapor deposition (PVD), spin coating, printing techniques, solution processing, or the like. In some embodiments, the light-absorbing layer is made of a perovskite material.

In some embodiments, the P2 line is achieved by laser scribing. The P2 line can isolate light-absorbing layers between different cell units and grooves formed by the P2 line may be configured to connect the different cell units to form a series connection. In some embodiments, the groove formed by the P2 line is filled with an electrically conductive material, e.g., a conductive paste, conductive ink, or metal coating.

A distance between a position of the P1 line and a position of the P2 line needs to be as small as possible to minimize an ineffective region, and also large enough to avoid leakage along edges. In some embodiments, a distance between the position of the P1 line and the position of the P2 line is in a range of 10 microns to 900 microns. For example, the distance is in a range of 50 microns to 500 microns, 100 microns to 300 microns, or the like.

FIG. 8 is a schematic diagram illustrating a P2 line according to some embodiments of the present disclosure. As shown in FIG. 8, the P2 line may be scribed on the light-absorbing layer 53 to form grooves formed by the P2 line, and the front electrode layer 52 at a bottom of the groove formed by the P2 line is exposed. A plurality of P2 lines may be scribed at different positions of the sub-cell pack to form a plurality of grooves formed by the P2 lines.

In 630, a back electrode layer may be laid on the light-absorbing layer and in the groove formed by the P2 line. The P3 line may be scribed on the back electrode layer close to the P2 line, and the P3 line may scribe off the back electrode layer and the light-absorbing layer, the front electrode layer 52 at a bottom of a groove formed by the P3 line may be exposed, and a sub-cell pack composed of a positive electrode tab, a negative electrode tab, and a plurality of cell units that are arranged horizontally may be obtained.

More descriptions of the back electrode layer, the P3 line, the positive electrode tab, the negative electrode tab, and the cell unit can be found in FIG. 1 and the related descriptions thereof. A horizontal direction is a direction pointed by the arrow B in FIG. 1.

The back electrode layer may be laid on a surface of the light-absorbing layer and in the groove formed by the P2 line, i.e., the back electrode layer in the groove formed by the P2 line may contact the front electrode layer at the bottom of the groove formed by the P2 line. In some embodiments, a manner of laying the rear electrode layer includes sputtering deposition, evaporation deposition, chemical vapor deposition (CVD) plating, printing techniques, or the like. In some embodiments, the back electrode layer is made of aluminum, silver, or other conductive metallic materials.

In some embodiments, the P3 line can be achieved by laser scribing. The P3 line may penetrate through the light-absorbing layer and the back electrode layer, and isolate light-absorbing layers and back electrode layers between different cell units.

A distance between a position of the P2 line and a position of the P3 line needs to provide enough space to ensure an effective series connection between cell units. A proper distance helps to optimize the conductive paths and reduce the current impedance; while also ensuring it is not too small to avoid short circuits. In some embodiments, a distance between the position of the P2 line and the position of the P3 line is in a range of 10 microns to 900 microns. For example, the distance is in a range of 50 microns to 500 microns, 100 microns to 300 microns, or the like.

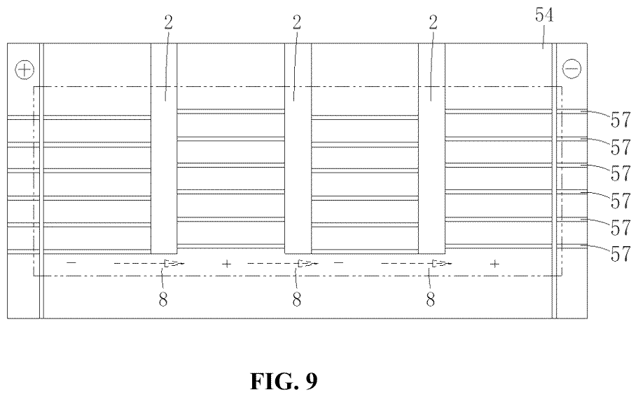

FIG. 9 is a schematic diagram illustrating a P3 line according to some embodiments of the present disclosure. As shown in FIG. 9, the P3 line may scribe off the back electrode layer 54 and the light-absorbing layer 53 to form the groove formed by the P3 line, and the front electrode layer 52 at a bottom of a groove formed by the P3 line is exposed. A plurality of P3 lines may be scribed in different positions of the sub-cell pack to form a plurality grooves formed by the P3 lines.

In 640: a P4 line may be scribed at a position of an intermediate insulation strap on the back electrode layer, the P4 line may expose the substrate at a bottom of the intermediate insulation strap, and a position of the intermediate connection strap may be retained on the back electrode layer.

More descriptions of the intermediate insulation strap and the intermediate connection strap can be found in FIG. 1 and the related descriptions thereof.

In some embodiments, the P4 line may be achieved by laser scribing. The P4 line may penetrate through the intermediate insulation strap to separate different sub-cell packs.

In 650, edges around a region where the sub-cell pack is located may be isolated to expose the substrate at a bottom of an isolated region. A plurality of sub-cell packs arranged longitudinally and series-connected in sequence through the intermediate connection strap may be obtained. Positions of positive polarities and negative polarities of two adjacent sub-cell packs may be reversed, and negative electrode tabs and positive electrode tabs between two adjacent sub-cell packs may be electrically connected through the intermediate connection strap, respectively.

Edge isolation refers to a process during solar cell manufacturing in which conductive regions at edges of the silicon wafer are removed or passivated. A main purpose of edge isolation is to remove conductive paths from the edges of the silicon wafer to avoid short circuits between edges of cells, thereby improving cell performance and efficiency. An isolated region may be a region where an edge isolation operation is performed. The isolated region may be a peripheral region of the sub-cell pack. In some embodiments, the edge isolation operation is achieved by an automated isolating device.

In 660, a positive electrode busbar may be conductively laid on a surface of the back electrode layer of the positive electrode tab of the leftmost sub-cell pack at a starting end, and the negative electrode busbar may be conductively laid on a surface of the back electrode layer of the negative electrode tab of the rightmost sub-cell pack at an ending end. The positive electrode busbar and the negative electrode busbar may be both located on a same side of the perovskite solar cell module.

More descriptions of the positive electrode busbar and the negative electrode busbar can be found in FIG. 1 and the related descriptions thereof. The leftmost starting end refers to a starting end of the arrow A in FIG. 1, and the rightmost ending end refers to an ending end end of the arrow A in FIG. 1.

A plurality of sub-cell packs may be series-connected to form an internally same-side series-connected perovskite solar cell module through a positive electrode busbar and a negative electrode busbar on a same side. The positive electrode busbar and the negative electrode busbar can collect and conduct the current from the sub-cell packs, pooling the outputs of the sub-cell packs to achieve electrical connection and power output for the cell module.

In embodiments of the present disclosure, the back electrode layer functions as a conductor connecting the sub-cell packs through laser scribing, thereby achieving the series connection of the internally same-side series-connected perovskite solar cell module. This approach replaces traditional busbars, allowing for internal series connection between the sub-cell packs of the perovskite solar cell module without the need for busbars, thereby avoiding issues such as scratching the thin film of the back electrode layer during encapsulation when realizing series connection through busbars, or even leading to internal short circuits within the perovskite solar cell module and reducing its power generation efficiency.

In some embodiments, the P1 line, the P2 line, and the P3 line in each of two adjacent sub-cell packs are arranged in different orders. In one of the sub-cell packs, the P1 line, the P2 line, and the P3 line are arranged in a front-to-back order (i.e., in an opposite direction indicated by an arrow D shown in FIG. 3). In the other sub-cell pack, the P1 line, the P2 line, and the P3 line are arranged in a back-to-front order (i.e., in a direction indicated by the arrow D shown in FIG. 3). The P2 lines in two sub-cell packs may be co-lined.

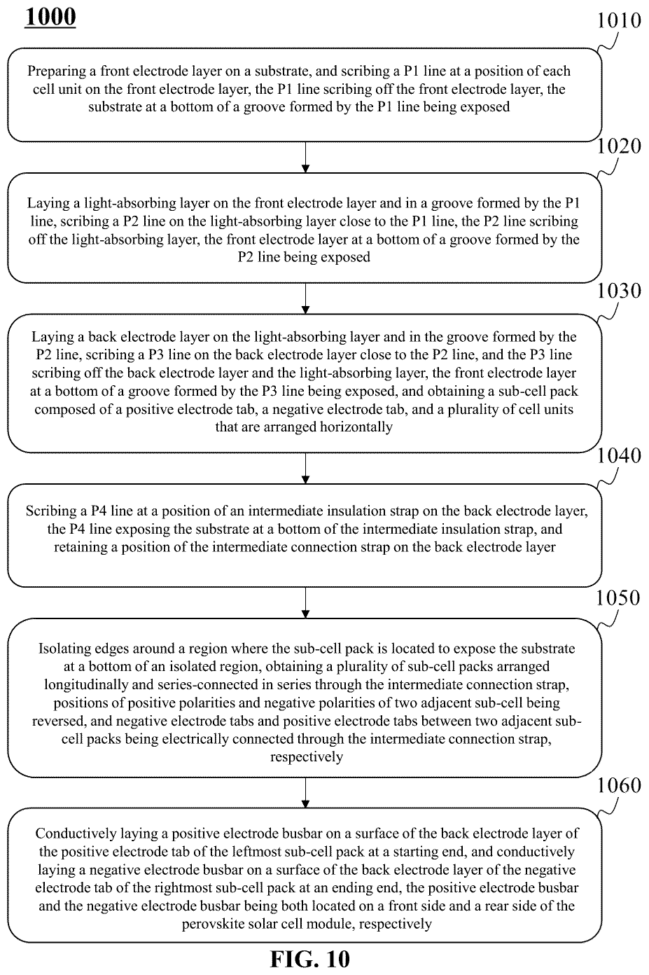

FIG. 10 is a flowchart illustrating a process for preparing an internally opposite-side series-connected perovskite solar cell module according to some embodiments of the present disclosure. In some embodiments, a process 1000 may be performed manually or by a system for preparing a perovskite solar cell module.

As shown in FIG. 10, the process 1000 includes following operations.

In 1010, a front electrode layer may be prepared on a substrate, and a P1 line may be scribed at a position of each cell unit on the front electrode layer. The P1 line may scribe off the front electrode layer, and the substrate at a bottom of a groove formed by the P1 line may be exposed. The operation 1010 is the same as the operation 610 of process 600.

In 1020, a light-absorbing layer may be laid on the front electrode layer and in the groove formed by the P1 line. A P2 line may be scribed on the light-absorbing layer close to the P1 line. The P2 line may scribe off the light-absorbing layer, and the front electrode layer at a bottom of a groove formed by the P2 line may be exposed. The operation 1020 is the same as the operation 620 of process 600.

In 1030: a back electrode layer 54 may be laid on the light-absorbing layer and in the groove formed by the P2 line. A P3 line may be scribed on the back electrode layer close to the P2 line, and the P3 line may scribe off the back electrode layer and the light-absorbing layer, the front electrode layer at a bottom of a groove formed by the P3 line may be exposed, and a sub-cell pack composed of a positive electrode tab, a negative electrode tab, and a plurality of cell units that are arranged horizontally may be obtained. The operation 1030 is the same as the operation 630 of process 600.

In 1040, a P4 line may be scribed at a position of an intermediate insulation strap on the back electrode layer, the P4 line may expose the substrate at a bottom of the intermediate insulation strap, and a position of the intermediate connection strap may be retained on the back electrode layer. Step 1040 is the same as step 640 of process 600.

In 1050, edges around a region where the sub-cell pack is located may be isolated to expose the substrate at a bottom of an isolated region. A plurality of sub-cell packs arranged longitudinally and series-connected in series through the intermediate connection strap may be obtained. Positions of positive polarities and negative polarities of two adjacent sub-cell packs may be reversed, and negative electrode tabs and positive electrode tabs between two adjacent sub-cell packs may be electrically connected through the intermediate connection strap, respectively.

More descriptions of the edge isolation operation and the isolated region can be found in the process 600 and the related descriptions thereof.

In 1060, a positive electrode busbar may be conductively laid on a surface of the back electrode layer of the positive electrode tab of the leftmost sub-cell pack at a starting end, and a negative electrode busbar may be conductively laid on a surface of the back electrode layer of the negative electrode tab of the rightmost sub-cell pack at an ending end. The positive electrode busbar and the negative electrode busbar may be both located on a front side and rear side of the perovskite solar cell module.

More descriptions of the positive electrode busbar and the negative electrode busbar can be found in FIG. 2 and the related descriptions thereof. The leftmost starting end refers to a starting end of the arrow A in FIG. 2, and the rightmost ending end refers to an ending end of the arrow A in FIG. 2.

A plurality of sub-cell packs are series-connected to form the internally opposite-side series-connected perovskite solar cell module through the positive electrode busbar and the negative electrode busbar on a front side and rear side, the series connection strap, and the insulation groove. The positive electrode busbar and the negative electrode busbar collect and conduct the current from the sub-cell packs, pooling the outputs of the sub-cell packs to achieve electrical connection and power output for the cell module.

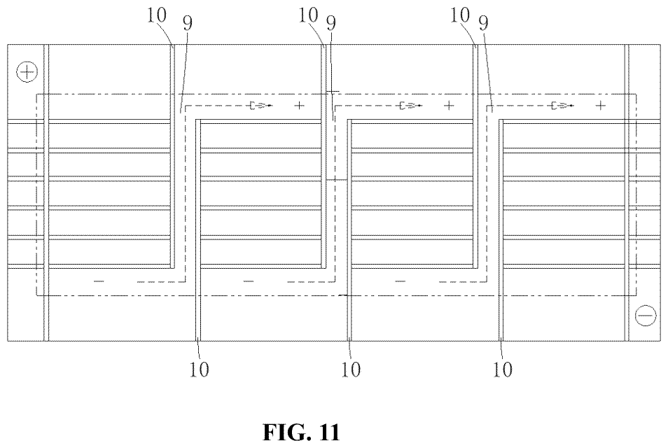

FIG. 11 is a schematic diagram illustrating a series connection strap and insulation groove according to some embodiments of the present disclosure. A dashed line with an arrow in FIG. 11 denotes a conduction direction of electrons within a perovskite solar cell module. As shown in FIG. 11, a current flowing out of a former sub-cell pack may flow into the positive electrode tab 3 of a latter sub-cell pack through the negative electrode tab 4 and the series connection strap 9. On both sides of the series connection strap 9, the insulation groove 10 may be provided, along with the sub-cell pack 1 adjacent to the insulation groove 10. The insulation groove 10 can avoid short-circuiting or unnecessary current leakage.

In embodiments of the present disclosure, the back electrode layer functions as a conductor connecting the sub-cell packs through an appropriate laser scribing process, thereby achieving the series connection of the perovskite solar cell module. This approach replaces traditional busbars, allowing for internal series connection between the sub-cell packs of the perovskite solar cell module without the need for busbars, thereby avoiding issues such as scratching the thin film of the back electrode layer during encapsulation when realizing series connection through busbars, or even leading to internal short circuits within the perovskite solar cell module and reducing its power generation efficiency.

In some embodiments, the P1 line, the P2 line, and the P3 line in each of two adjacent sub-cell packs are arranged in a same order, and the P1 line, the P2 line, and the P3 line in each of the two adjacent sub-cell packs are co-lined, respectively. For example, in two adjacent sub-cell packs, the P1 line, the P2 line, and the P3 line in each of two adjacent sub-cell packs are arranged in a front-to-back order (i.e., in an opposite direction indicated by the arrow D shown in FIG. 3) or a back-to-front order (i.e., in a direction indicated by the arrow D shown in FIG. 3).

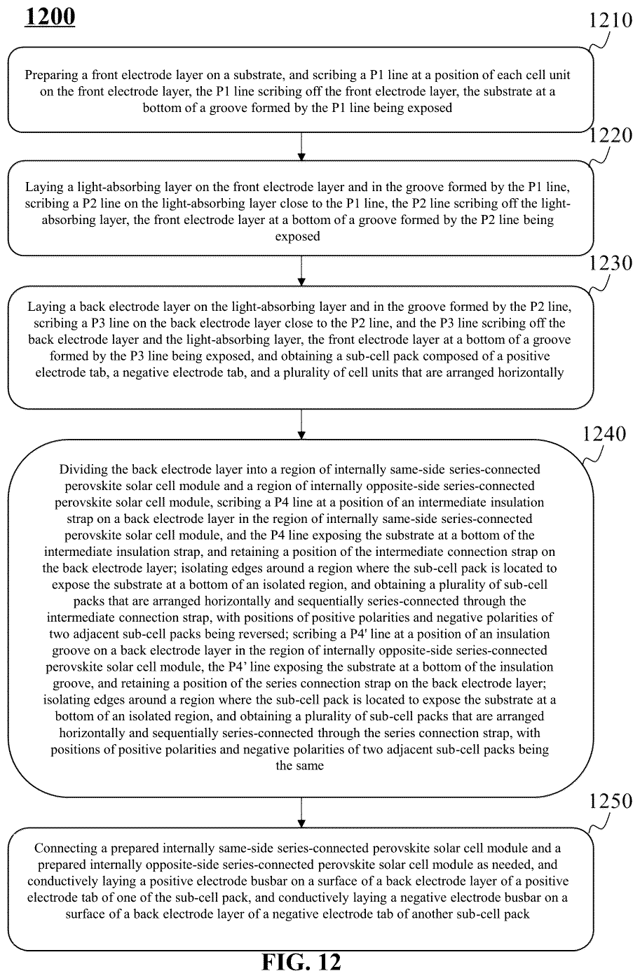

FIG. 12 is a flowchart illustrating a process for preparing an internally series-connected perovskite solar cell module according to some embodiments of the present disclosure. In some embodiments, a process 1200 may be performed manually or by a system for preparing a perovskite solar cell module.

As shown in FIG. 12, the process 1200 includes following operations.

In 1210, a front electrode layer may be prepared on a substrate, and a P1 line may be scribed at a position of each cell unit on the front electrode layer. The P1 line may scribe off the front electrode layer, and the substrate at a bottom of a groove formed by the P1 line may be exposed. The operation 1210 is the same as the operation 610 of process 600.

In 1220, a light-absorbing layer may be laid on the front electrode layer and in the groove formed by the P1 line. A P2 line may be scribed on the light-absorbing layer close to the P1 line. The P2 line may scribe off the light-absorbing layer, and the front electrode layer at a bottom of a groove formed by the P2 line may be exposed. The operation 1220 is the same as the operation 620 of process 600.

In 1230, a back electrode layer may be laid on the light-absorbing layer and in the groove formed by the P2 line. A P3 line may be scribed on the back electrode layer close to the P2 line, and the P3 line may scribe off the back electrode layer and the light-absorbing layer, the front electrode layer at a bottom of a groove formed by the P3 line may be exposed, and a sub-cell pack composed of a positive electrode tab, a negative electrode tab, and a plurality of cell units that are arranged horizontally may be obtained. The operation 1230 is the same as the operation 630 of process 600.

In 1240, the back electrode layer may be divided into a region of internally same-side series-connected perovskite solar cell module and a region of internally opposite-side series-connected perovskite solar cell module, a P4 line may be scribed at a position of an intermediate insulation strap on a back electrode layer in the region of internally same-side series-connected perovskite solar cell module, and the P4 line may expose the substrate at a bottom of the intermediate insulation strap, and a position of the intermediate connection strap on the back electrode layer may be retained; edges around a region where the sub-cell pack is located may be isolated to expose the substrate at a bottom of an isolated region, and a plurality of sub-cell packs that are arranged horizontally and sequentially series-connected through the intermediate connection strap may be obtained, with positions of positive polarities and negative polarities of two adjacent sub-cell packs being reversed; a P4′ line may be scribed at a position of an insulation groove on a back electrode layer in the region of internally opposite-side series-connected perovskite solar cell module, the P4′line may expose the substrate at a bottom of the insulation groove, and a position of the series connection strap on the back electrode layer may be retained; edges around a region where the sub-cell pack is located may be isolated to expose the substrate at a bottom of an isolated region, and a plurality of sub-cell packs that are arranged horizontally and sequentially series-connected through the series connection strap may be obtained, with positions of positive polarities and negative polarities of two adjacent sub-cell packs being the same.

More descriptions of an edge isolation operation, an isolated region, and the P4 line can be found in the process 600 and the related descriptions thereof. More descriptions of the internally same-side series-connected perovskite solar cell module can be found in FIG. 6 and the related descriptions thereof. More descriptions of the internally opposite-side series-connected perovskite solar cell module can be found in FIG. 10 and the related descriptions thereof. The P4′ line is similar to the P4 line.

In 1250, a prepared internally same-side series-connected perovskite solar cell module and a prepared internally opposite-side series-connected perovskite solar cell module may be connected as needed, and a positive electrode busbar may be conductively laid on a surface of a back electrode layer of a positive electrode tab of one of the sub-cell pack, and a negative electrode busbar may be conductively laid on a surface of a back electrode layer of a negative electrode tab of another sub-cell pack.

More descriptions of the positive electrode busbar and the negative electrode busbar can be found in FIG. 1 and the related descriptions thereof. A plurality of sub-cell packs are series-connected to form an internally series-connected perovskite solar cell module through the positive electrode busbar and the negative electrode busbar.

It should be noted that the foregoing descriptions of the process 600, the process 1000, and the process 1200 are intended to be exemplary and illustrative only, and do not limit the scope of application of the present disclosure. For a person skilled in the art, various corrections and changes can be made to the process 600, the process 1000, and the process 1200 under the guidance of the present disclosure. However, these corrections and changes remain within the scope of the present disclosure.

The foregoing is only a preferred embodiment of the present disclosure and is not intended to limit the present disclosure, and any modifications, equivalent substitutions, improvements, etc., made within the spirit and principles of the present disclosure shall be included in the scope of protection of the present disclosure.

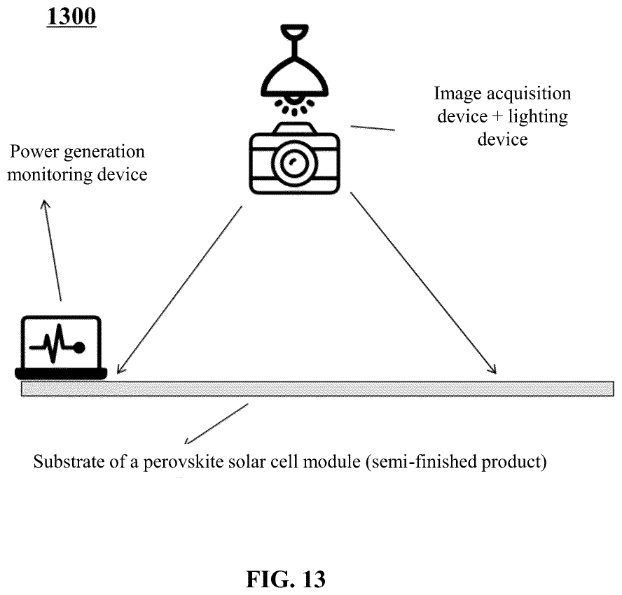

Some embodiments of the present disclosure also provide a system for preparing a perovskite solar cell module. FIG. 13 is a schematic diagram illustrating a system for preparing a perovskite solar cell module according to some embodiments of the present disclosure.

In some embodiments, as shown in FIG. 13, a system 1300 for preparing a perovskite solar cell module includes a processor (not shown in the figure), an image acquisition device, a lighting device, and a power generation monitoring device.

The processor may process data and/or information obtained from other devices or system components. The processor may execute program instructions based on such data, information, and/or processing results to perform one or more of the functions described in embodiments of the present disclosure. By way of example only, the processor may include a central processing unit (CPU), an application-specific integrated circuit (ASIC), etc., or any combination of the above. In some embodiments, the processor includes a plurality of modules, and different modules are used to execute different program instructions separately.

The image acquisition device may be a device that captures an image. In some embodiments, the image acquisition device includes a camera (e.g., a CCD camera), a video camera, a webcam, an infrared camera, or the like.

The lighting device may be a device that provides light. In some embodiments, the lighting device includes an incandescent lamp, a fluorescent lamp, a halogen lamp, a gas discharge lamp, a light-emitting diode, or the like.

The power generation monitoring device may be a device or system that monitors and manages performance and status of a power generation system in real-time. In some embodiments, the power generation monitoring device includes functions such as data acquisition, data transmission, data processing and analysis, visualization interface, and historical data storage.

In some embodiments, the processor is communicatively connected to the image acquisition device, the lighting device, and the power generation monitoring device. The processor may obtain an image related to a solar cell module through the image acquisition device. The processor may be configured to control the lighting device to be turned on or off. The processor may obtain information about power generation of the solar cell module through the power generation monitoring device.

In some embodiments, the image acquisition device, the lighting device, and/or the power generation monitoring device are secured to a robotic arm, and the robotic arm moves in response to a command issued by the processor to cause the image acquisition device, the lighting device, and/or the power generation monitoring device to be moved to different positions.

In some embodiments, the processor controls the robotic arm to keep the image acquisition device above perpendicular to a substrate (as shown in FIG. 13). The processor may be configured to monitor a perovskite solar module before and after an edge isolation operation through the image acquisition device and evaluate an edge isolation effect based on a monitoring result.

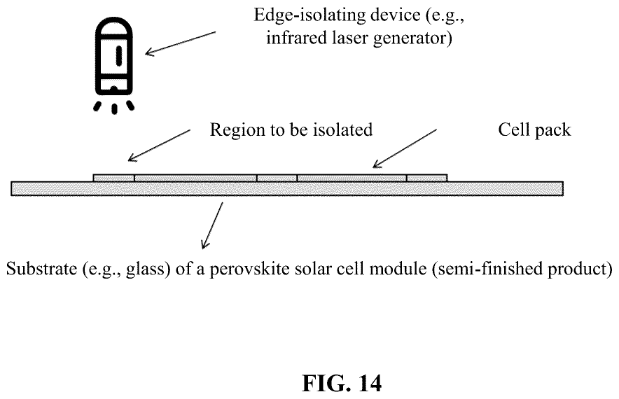

More descriptions of the edge isolation operation can be found in the previous section. In some embodiments, the edge isolation operation is accomplished by automating the edge isolation operation with an automated edge-isolating device, as shown in FIG. 14. For example, the automated edge-isolating device may perform the edge isolation operation on a region to be isolated based on a preset edge isolation parameter (e.g., a preset edge isolation trajectory). The preset edge isolation trajectory is related to a count of cell units in a sub-cell pack. In some embodiments, the edge-isolating device includes a laser generator (e.g., an infrared laser generator) that removes a front electrode layer, a light-absorbing layer, and a back electrode layer in the region to be isolated by a laser.

In some embodiments, the processor obtains substrate image data of the perovskite solar cell module before and after the edge isolation operation through the image acquisition device. The substrate image data may be image data of a perovskite solar cell module with a substrate. The perovskite solar cell module may be a semi-finished product.

The substrate image data may be used as a monitoring result. The processor may compare and analyze the substrate image data before and after the edge isolation operation to evaluate an edge isolation result.

In some embodiments, the processor obtains, before and after performing the edge isolation operation, the substrate image data of the perovskite solar cell module through the image acquisition device; issues a notification of an isolating effect based on the substrate image data; and, in response to determining the notification of an isolating effect as an edge not being isolated thoroughly, the edge-isolating device is controlled to perform the edge isolation operation on the perovskite solar cell module based on updated preset edge isolation parameters.

A notification of an isolating effect may be a notification that indicates whether or not an isolating effect is complete. The notification of the isolating effect may include an edge being isolated thoroughly and an edge not being isolated thoroughly. More descriptions of determining whether an edge is isolated thoroughly can be found in related descriptions later.

In some embodiments, the processor obtains first substrate image data through the image acquisition device before the edge isolation operation; determines a baseline image based on the first substrate image data and preset preparation parameters; obtains second substrate image data through the image acquisition device after the edge isolation operation; determines an isolating effect value based on the baseline image and the second substrate image data; and issues the notification of an isolating effect based on the isolating effect value.

The preset preparation parameters may be preset parameters for preparing a cell module. The preset preparation parameters may be determined according to user requirements. In some embodiments, the preset preparation parameters includes a count of cell units and sub-cell packs.

The baseline image may be a standard isolated image whose edges are isolated thoroughly for comparison. In some embodiments, the processor automatically generates the baseline image. For example, one or more localized standard isolated images are superimposed overlaying a first substrate image based on the count of cell units and sub-cell packs in the preset preparation parameter, and a standard isolated image, i.e., the baseline image is generated. The localized standard isolated image may be a standard isolated image of one cell unit.

The isolating effect value may be a numerical value that reflects an isolating effect. The isolating effect value may be expressed as a numerical value in a range of 0 to 1, including 0 or 1. The lower the isolating effect value, the less thoroughly the edge is isolated.

In some embodiments, the processor determines the isolating effect value based on the baseline image and the second substrate image data through an edge-isolating model.

In some embodiments, the edge-isolating model is a machine learning model. In some embodiments, the edge-isolating model is a Convolutional Neural Network (CNN) model and a Deep Neural Network (DNN) model, or the like. The edge-isolating model may also be a machine learning model of another structure, such as a neural network model, a recurrent neural network model, or the like.

In some embodiments, inputs to the edge-isolating model include the baseline image and the second substrate image data, and an output includes the isolating effect value.

In some embodiments, the processor obtains a plurality of first training samples with a first label to constitute a first training sample set and train the first training sample set to obtain the edge-isolating model.

In some embodiments, the first training sample of the edge-isolating model includes a sample baseline image and sample second substrate image data. The first label may be an isolating effect value corresponding to the first training sample. The first training sample may be obtained from historical data, e.g., by generating the first training sample based on substrate image data of a historical preparation process. The first label may be determined by a system or human labeling. For example, the first label is manually determined based on a count of positions of insolated edges in the region to be isolated. The greater the count of positions of insolated edges, the lower a value of the first label.

In some embodiments, the processor inputs the first training sample set into an initial edge-isolating model to perform a plurality of rounds of iterations. Each round of iteration may include: selecting one or more first training samples from the first training sample set, inputting the one or more first training samples into the initial edge-isolating model to obtain a model prediction output corresponding to the one or more first training samples; calculating a value of a loss function by introducing the model prediction output corresponding to the one or more first training samples, and a label of the one or more first training samples into a formula for a predefined loss function; and inversely updating model parameters in the initial edge-isolating model based on the value of the loss function. When an end-of-iteration condition is satisfied, the iteration is ended, and a trained edge-isolating model may be obtained. The end-of-iteration condition may be that the loss function converges, a count of iterations reaches a threshold, etc.

In embodiments of the present disclosure, determining the isolating effect value through the edge-isolating model can utilize the self-learning capability of the machine learning model to find a law from a large amount of historical data, and to obtain a relationship between the second baseline image data, the baseline image, and the isolating effect value, etc., thereby improving the accuracy and efficiency of determining the isolating effect value.

In some embodiments, in response to determining the isolating effect value being less than an effect threshold, the processor issues a notification of an isolating effect indicating that the edge is not isolated thoroughly to facilitate the evaluation of an overall isolating effect. The effect threshold may be set empirically, e.g., 0.8, 0.9, or 1, etc.

In some embodiments, in response to determining the isolating effect value not being less than the effect threshold, the processor issues a notification of an isolating effect indicating that the edge is isolated thoroughly. When the isolating effect value is less than the effect threshold, a process for preparing the solar module cell may continue to be performed.

In some embodiments, in response to a notification of an isolating effect indicating the edge is not isolated thoroughly, the processor updates preset edge isolation parameters. The preset edge isolation parameters may include a preset edge isolation speed. The processor may multiply current preset edge isolation parameters by the isolating effect value to obtain updated preset edge isolation parameters. The processor performs the edge isolation operation on the perovskite solar cell module based on the updated preset edge isolation parameters.

In some embodiments, in response to determining the notification of isolating effect indicating the edge being not isolated thoroughly, the processor adjusts a laser emission power of the edge-isolating device (e.g., a laser transmitter) to perform the edge isolation operation.

In embodiments of the present disclosure, by determining the isolating effect based on the baseline image, it is possible to decide, based on the isolating effect, whether or not to repeat the edge isolation operation, thereby improving the isolating quality and the isolating efficiency. Additionally, according to the isolating effect, the preset isolation parameters of the isolating device are automatically regulated, which can increase an automation degree of cell preparation and improve the quality of the production.

In embodiments of the present disclosure, by monitoring the cell module before and after the edge isolation operation, it is possible to improve the efficiency of isolating the edges, and based on the isolating effect, it is possible to decide whether or not to repeat the edge isolation operation and improve the isolating quality.

In some embodiments, the processor is configured to light the perovskite solar cell module through the lighting device during the preparation process; detect a current magnitude and a voltage magnitude of one or more sub-cell packs through the power generation monitoring device; and assess presence of a failure based on the current magnitude and the voltage magnitude.

In some embodiments, the power generation monitoring device includes a current monitoring component (e.g., an ammeter) and a voltage monitoring component (e.g., a voltmeter). The current monitoring component may detect a current magnitude of one or more cell packs, and the voltage monitoring component may detect a voltage magnitude of one or more cell packs. The power generation monitoring device may form a loop with a positive electrode busbar and a negative electrode busbar, as well as a sub-cell pack between the positive electrode busbar and the negative electrode busbar, so as to measure the current magnitude and the voltage magnitude.

The failure may include short circuits due to improper scribing. In some embodiments, in response to determining the voltage magnitude not being greater than a preset voltage threshold or the current magnitude being less than a preset current threshold, the processor determines that a failure is present. The preset voltage threshold and the preset current threshold may be set artificially based on experience. For example, the preset voltage threshold is 0.

In embodiments of the present disclosure, by detecting the current magnitude and voltage magnitude of a cell pack, a failure region can be detected promptly during the production process, reducing costs to ensure the quality of cell preparation and improving the yield rate.

In some embodiments, after laying the positive electrode busbar and the negative electrode busbar in the process 600, the process 1000, and the process 1200, the processor is further configured to control the lighting device to light the perovskite solar cell module, detect a current magnitude and a voltage magnitude of one or more cell packs through the power generation monitoring device, and generates a scribing failure risk value of the one or more cell packs based on the current magnitude and the voltage magnitude.

The processor may issue a control command to control the lighting device to light the perovskite solar cell module. The lighting device may be provided on the same robotic arm as the image acquisition device. The perovskite solar cell module may be a semi-finished product.

The scribing failure risk value may be a risk scenario of failure due to scribing. A higher scribing failure risk value indicates a more likely failure.

In some embodiments, the processor determines a standard voltage and a standard current for a sub-cell pack when it is normally failure-free based on a large amount of historical preparation data; and determines the scribing failure risk value based on the voltage magnitude, the current magnitude, and the standard voltage and standard current.

In some embodiments, the processor designates an average of a voltage magnitude and a current magnitude of a sub-cell pack from a large amount of historical preparation data when it is normally failure-free as the standard voltage and the standard current.

In some embodiments, the processor obtains a voltage ratio based on a ratio of a detected voltage magnitude and the standard voltage, and obtains a current ratio based on a ratio of a detected current magnitude and the standard current. The processor may subtract 1 from the lesser among the voltage ratio and the current ratio as the scribing failure risk value. For example, if the voltage ratio is greater than the current ratio, the processor subtracts 1 from the current ratio to obtain the scribing failure risk value. For example, if the voltage ratio is less than the current ratio, the processor subtracts 1 from the voltage ratio to obtain the scribing failure risk value.

In some embodiments, the processor generates the scribing failure risk value based on the current magnitude and the voltage magnitude using a scribing model.

In some embodiments, the scribing model is a machine learning model. In some embodiments, the scribing model is a Convolutional Neural Network (CNN) model and a Deep Neural Network (DNN) model, or the like. The scribing model may also be a machine learning model of another structure, such as a neural network model, a recurrent neural network model, or the like.

In some embodiments, inputs to the scribing model include the current data, the voltage data, the count of sub-cell packs, and the count of cell units, and an output includes the scribing failure risk value. The current data and the voltage data may be sequential data at multiple time points. The count of sub-cell packs and the count of cell units may be determined based on the preset preparation parameters.

In some embodiments, the processor obtains a plurality of second training samples with a second label to form a second training sample set, and train the second training sample set to obtain the scribing model.

In some embodiments, the second training sample of the scribing model includes sample voltage data, sample current data, a sample count of sub-cell packs, and a sample count of cell units. The second label may be a scribing failure risk value corresponding to the second training sample. The second training sample may be obtained from historical data, e.g., by generating the second training sample based on data from a historical preparation process. The second label may be determined by systematic or human labeling. For example, the second label is determined based on a proportion of defects detected during subsequent product testing (e.g., pre-shipment inspection) of perovskite solar cell module historically prepared corresponding to the second training sample. For the product detection corresponding to the same batch of the second training sample, if the proportion of defects is 15%, the scribing failure risk value may be marked as 15%, i.e., 0.15. The same batch of the second training sample may be a second training sample that has the same or similar sample values (e.g., a difference is not greater than 5%).

A training process of the scribing model is similar to that of the edge-isolating model and will not be repeated here.

In embodiments of the present disclosure, determining the scribing failure risk value through the scribing model can utilize the self-learning capability of a machine learning model to find a law from a large amount of historical data and obtain a relationship between the current magnitude, the voltage magnitude and the scribing failure risk value, or the like, thereby improving the accuracy and efficiency of determining the scribing failure risk value.

In some embodiments, the processor also marks different batches of perovskite solar cell modules based on the scribing failure risk value, and determines whether to discard the batch of perovskite solar cell modules based on a marking. For example, the processor marks the perovskite solar cell module with a scribing failure risk value greater than a preset failure threshold, and the processor discards the marked perovskite solar cell module.

In some embodiments, the processor also applies different detection parameters to the product detection (e.g., pre-shipment inspection) after the preparation has been completed. For example, if the scribing failure risk value is higher, the intensity of product detection increases, the detection becomes more comprehensive, and additional detection items are added.

In embodiments of the present disclosure, by detecting the current magnitude and voltage magnitude of a cell pack, it is possible to conveniently detect problematic cell packs during the manufacturing process, allowing for timely adjustments to the production process, thereby preventing negative impacts on product quality and reducing the likelihood of issues occurring.

One or more embodiments of the present disclosure provide a device for preparing a perovskite solar cell module, comprising a processor. The processor is configured to perform a method for preparing a perovskite solar cell module as described in any of the embodiments of the present disclosure.

One or more embodiments of the present disclosure provide a computer-readable storage medium. The storage medium stores computer instructions, and when a computer reads the computer instructions in the storage medium, the computer executes a method for preparing a perovskite solar cell module of any one of embodiments of the present disclosure.

The basic concepts have been described above, and it is apparent to those skilled in the art that the foregoing detailed disclosure is intended as an example only and does not constitute a limitation of the present disclosure. While not expressly stated herein, a person skilled in the art may make various modifications, improvements, and amendments to the present disclosure. Those types of modifications, improvements, and amendments are suggested in the present disclosure, so those types of modifications, improvements, and amendments remain within the spirit and scope of the exemplary embodiments of the present disclosure.

Also, the present disclosure uses specific words to describe embodiments of the present disclosure. Such as “an embodiment,” “one embodiment,” and/or “some embodiments” means a feature, structure, or characteristic associated with at least one embodiment of the present disclosure. Accordingly, it should be emphasized and noted that “an embodiment” or “one embodiment” or “an alternative embodiment” in different places in the present disclosure do not necessarily refer to the same embodiment. In addition, certain features, structures, or characteristics of one or more embodiments of the present disclosure may be suitably combined.

Additionally, the order in which the elements and sequences are processed in the present disclosure, the use of numerical letters, or the use of other names is not intended to qualify the order of the processes and methods of the present disclosure, unless expressly stated in the claims. While some embodiments of the invention that are currently considered useful are discussed in the foregoing disclosure by way of various examples, it should be appreciated that such details serve only illustrative purposes, and that additional claims are not limited to the disclosed embodiments, rather, the claims are intended to cover all amendments and equivalent combinations that are consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be noted that in order to simplify the presentation of the present disclosure, and thereby aid in the understanding of one or more embodiments of the invention, the foregoing descriptions of embodiments of the present disclosure sometimes set multiple features together in a single embodiment, accompanying drawings, or a description thereof. However, this method of disclosure does not imply that the objects of the present disclosure require more features than those mentioned in the claims. Rather, claimed subject matter may lie in less than all features of a single foregoing disclosed embodiment.

Some embodiments use numbers to describe the number of components and attributes, and it should be understood that such numbers used in the description of the embodiments are modified in some examples by the modifiers “about,” “approximately,” or “substantially”. Unless otherwise noted, the terms “about,” “approximately,” or “substantially” indicate that a ±20% variation in numbers is allowed. Correspondingly, in some embodiments, the numerical parameters used in the present disclosure and claims are approximations, which can change depending on the desired characteristics of individual embodiments. In some embodiments, the numerical parameters should consider the specified number of valid digits and employ general place-keeping. While the numerical domains and parameters used to confirm the breadth of their ranges in some embodiments of the present disclosure are approximations, in specific embodiments, such values are set to be as precise as possible within a feasible range.

For each of the patents, patent applications, patent application disclosures, and other materials cited in the present disclosure, such as articles, books, specification sheets, publications, documents, etc., the entire contents of which are hereby incorporated herein by reference. Application history documents that are inconsistent with or conflict with the contents of the present disclosure are excluded, as are documents (currently or hereafter appended to the present disclosure) that limit the broadest scope of the claims of the present disclosure. It should be noted that in the event of any inconsistency or conflict between the descriptions, definitions, and/or use of terms in the materials appended to the present disclosure and the contents of the present disclosure, the descriptions, definitions, and/or use of terms in the present disclosure shall prevail.

Finally, it should be understood that the embodiments in the present disclosure are only used to illustrate the principles of the embodiments in the present disclosure. Other deformations may also fall within the scope of the present disclosure. As such, alternative configurations of embodiments of the present disclosure may be considered to be consistent with the teachings of the present disclosure as an example, not as a limitation. Correspondingly, the embodiments of the present disclosure are not limited to the embodiments expressly presented and described herein.

What is claimed is:

1. An internally same-side series-connected perovskite solar cell module, comprising a plurality of sub-cell packs arranged longitudinally, wherein,
positions of positive polarities and negative polarities of two adjacent sub-cell packs are reversed, and each sub-cell pack includes a positive electrode tab, a negative electrode tab, and a plurality of cell units that are arranged horizontally, the positive electrode tab and the negative electrode tab are located at a front side and a rear side of each sub-cell pack, respectively, the plurality of cell units are located between the positive electrode tab and the negative electrode tab, and negative electrode tab and positive electrode tab between the two adjacent sub-cell packs are electrically connected only through an intermediate connection strap, respectively, and remaining portions between the two adjacent sub-cell packs are isolated from each other through an intermediate insulation strap;
an internal structure of the positive electrode tab, the negative electrode tab, and the plurality of cell units includes a substrate, a front electrode layer, a light-absorbing layer, and a back electrode layer from bottom to top, and two adjacent cell units, the cell unit and the positive electrode tab, and the cell unit and the negative electrode tab, are respectively separated into sub-cell packs with an internal conductive connection by a scribing line group composed of a line P1, a line P2, and a line P3,
wherein the P1 line scribes off the front electrode layer, the substrate at a bottom of a groove formed by the P1 line is exposed, the P2 line is close to the P1 line in a same group and scribes off the light-absorbing layer, the front electrode layer at a bottom of a groove formed by the P2 line is exposed, and the groove formed by the P2 line is filled with an electrically-conductive material, the P3 line is close to the P2 line in a same group and scribes off the back electrode layer and the light-absorbing layer at the same time, and the front electrode layer at a bottom of a groove formed by the P3 line is exposed; and
a positive electrode busbar is conductively laid on a surface of a back electrode layer of a positive electrode tab of a leftmost sub-cell pack, and a negative electrode busbar is conductively laid on a surface of a back electrode layer of a negative electrode tab of a rightmost sub-cell pack, and the positive electrode busbar and the negative electrode busbar are both located on a same side of the perovskite solar cell module.

2. An internally opposite-side series-connected perovskite solar cell module, comprising a plurality of sub-cell packs arranged horizontally, wherein
positions of positive polarities and negative polarities of two adjacent sub-cell packs are the same, and each sub-cell pack includes a positive electrode tab, a negative electrode tab, and a plurality of cell units that are arranged horizontally, the positive electrode tab and the negative electrode tab are located at a front side and a rear side of each sub-cell pack, respectively, the plurality of cell units are located between the positive electrode tab and the negative electrode tab, and negative electrode tabs and positive electrode tabs between two adjacent sub-cell packs are electrically connected only through a series connection strap, respectively, insulation grooves and sub-cell packs adjacent to the insulation grooves are arranged on two sides of the series connection strap, respectively, the insulations grooves and the sub-cell packs adjacent to the insulation grooves are insulated from each other;
an internal structure of the positive electrode tab, the negative electrode tab, and the plurality of cell units includes a substrate, a front electrode layer, a light-absorbing layer, and a back electrode layer from bottom to top, and two adjacent cell units, the cell unit and the positive electrode tab, and the cell unit and the negative electrode tab, are respectively separated into sub-cell packs with an internal conductive connection by a scribing line group composed of a line P1, a line P2, and a line P3,
wherein the P1 line scribes off the front electrode layer, the substrate at a bottom of a groove formed by the P1 line is exposed, the P2 line is close to the P1 line in a same group and scribes off the light-absorbing layer, the front electrode layer at a bottom of a groove formed by the P2 line is exposed, and the groove formed by the P2 line is filled with an electrically-conductive material, the P3 line is close to the P2 line in the same group and scribes off the back electrode layer and the light-absorbing layer at the same time, and the front electrode layer at a bottom of a groove formed by the P3 line is exposed; and
a positive electrode busbar is conductively laid on a surface of a back electrode layer of a positive electrode tab of a leftmost sub-cell pack, and a negative electrode busbar is conductively laid on a surface of a back electrode layer of a negative electrode tab of a rightmost sub-cell pack, and the positive electrode busbar and the negative electrode busbar are both located on a front side and a rear side of the perovskite solar cell module, respectively.

3. An internally series-connected perovskite solar cell module, comprising the internally same-side series-connected perovskite solar cell module and the internally opposite-side series-connected perovskite solar cell module,
the internally same-side series-connected perovskite solar cell module, comprising a plurality of sub-cell packs arranged longitudinally, wherein,
positions of positive polarities and negative polarities of two adjacent sub-cell packs are reversed, and each sub-cell pack includes a positive electrode tab, a negative electrode tab, and a plurality of cell units that are arranged horizontally, the positive electrode tab and the negative electrode tab are located at a front side and a rear side of each sub-cell pack, respectively, the plurality of cell units are located between the positive electrode tab and the negative electrode tab, and negative electrode tab and positive electrode tab between the two adjacent sub-cell packs are electrically connected only through an intermediate connection strap, respectively, and remaining portions between the two adjacent sub-cell packs are isolated from each other through an intermediate insulation strap;
an internal structure of the positive electrode tab, the negative electrode tab, and the plurality of cell units includes a substrate, a front electrode layer, a light-absorbing layer, and a back electrode layer from bottom to top, and two adjacent cell units, the cell unit and the positive electrode tab, and the cell unit and the negative electrode tab, are respectively separated into sub-cell packs with an internal conductive connection by a scribing line group composed of a line P1, a line P2, and a line P3,
wherein the P1 line scribes off the front electrode layer, the substrate at a bottom of a groove formed by the P1 line is exposed, the P2 line is close to the P1 line in a same group and scribes off the light-absorbing layer, the front electrode layer at a bottom of a groove formed by the P2 line is exposed, and the groove formed by the P2 line is filled with an electrically-conductive material, the P3 line is close to the P2 line in a same group and scribes off the back electrode layer and the light-absorbing layer at the same time, and the front electrode layer at a bottom of a groove formed by the P3 line is exposed; and
a positive electrode busbar is conductively laid on a surface of a back electrode layer of a positive electrode tab of a leftmost sub-cell pack, and a negative electrode busbar is conductively laid on a surface of a back electrode layer of a negative electrode tab of a rightmost sub-cell pack, and the positive electrode busbar and the negative electrode busbar are both located on a same side of the perovskite solar cell module; and
the internally opposite-side series-connected perovskite solar cell module, comprising a plurality of sub-cell packs arranged horizontally, wherein
positions of positive polarities and negative polarities of two adjacent sub-cell packs are the same, and each sub-cell pack includes a positive electrode tab, a negative electrode tab, and a plurality of cell units that are arranged horizontally, the positive electrode tab and the negative electrode tab are located at a front side and a rear side of each sub-cell pack, respectively, the plurality of cell units are located between the positive electrode tab and the negative electrode tab, and negative electrode tabs and positive electrode tabs between two adjacent sub-cell packs are electrically connected only through a series connection strap, respectively, insulation grooves and sub-cell packs adjacent to the insulation grooves are arranged on two sides of the series connection strap, respectively, the insulations grooves and the sub-cell packs adjacent to the insulation grooves are insulated from each other;
an internal structure of the positive electrode tab, the negative electrode tab, and the plurality of cell units includes a substrate, a front electrode layer, a light-absorbing layer, and a back electrode layer from bottom to top, and two adjacent cell units, the cell unit and the positive electrode tab, and the cell unit and the negative electrode tab, are respectively separated into sub-cell packs with an internal conductive connection by a scribing line group composed of a line P1, a line P2, and a line P3,
wherein the P1 line scribes off the front electrode layer, the substrate at a bottom of a groove formed by the P1 line is exposed, the P2 line is close to the P1 line in a same group and scribes off the light-absorbing layer, the front electrode layer at a bottom of a groove formed by the P2 line is exposed, and the groove formed by the P2 line is filled with an electrically-conductive material, the P3 line is close to the P2 line in the same group and scribes off the back electrode layer and the light-absorbing layer at the same time, and the front electrode layer at a bottom of a groove formed by the P3 line is exposed; and
a positive electrode busbar is conductively laid on a surface of a back electrode layer of a positive electrode tab of a leftmost sub-cell pack, and a negative electrode busbar is conductively laid on a surface of a back electrode layer of a negative electrode tab of a rightmost sub-cell pack, and the positive electrode busbar and the negative electrode busbar are both located on a front side and a rear side of the perovskite solar cell module, respectively.

4. A method for preparing the internally same-side series-connected perovskite solar cell module of claim 1, comprising:
preparing the front electrode layer on the substrate, scribing the P1 line at a position of each cell unit on the front electrode layer, the P1 line scribing off the front electrode layer, and exposing the substrate at the bottom of the groove formed by the P1 line;
laying the light-absorbing layer on the front electrode layer and in the groove formed by the P1 line, scribing the P2 line on the light-absorbing layer close to the P1 line, and the P2 line scribing off the light-absorbing layer and exposing the front electrode layer at the bottom of the groove formed by the P2 line;
laying the back electrode layer on the light-absorbing layer and in the groove formed by the P2 line, scribing the P3 line on the back electrode layer close to the P2 line, and the P3 line scribing off the back electrode layer and light-absorbing layer, exposing the front electrode layer at the bottom of the groove formed by the P3 line, and obtaining the sub-cell pack composed of a positive electrode tab, a negative electrode tab, and a plurality of cell units that are arranged horizontally;
scribing the P4 line at a position of the intermediate insulation strap on the back electrode layer, and the P4 line exposing the substrate at a bottom of the intermediate insulation strap, and retaining a position of the intermediate connection strap on the back electrode layer;
isolating edges around a region where the sub-cell pack is located to expose the substrate at a bottom of an isolated region, and obtaining a plurality of sub-cell packs that are arranged horizontally and sequentially series-connected through the intermediate connection strap, with positions of positive electrode tabs and negative electrode tabs of two adjacent sub-cell packs being reversed; and
conductively laying the positive electrode busbar on the surface of the back electrode layer of the positive electrode tab of the leftmost sub-cell pack, and conductively laying the negative electrode busbar on the surface of the back electrode layer of the negative electrode tab of the rightmost sub-cell pack, and the positive electrode busbar and the negative electrode busbar being both located on the same side of the perovskite solar cell module.

5. The method for preparing the internally same-side series-connected perovskite solar cell module of claim 4, wherein in two adjacent sub-cell packs, the P1 line, the P2 line, and the P3 line in each of the two adjacent sub-cell packs are arranged in different orders, and in one of the sub-cell packs, the P1 line, the P2 line, and the P3 line are arranged in a front-to-back order, while in the other sub-cell pack, the P1 line, the P2 line, and the P3 line are arranged in a back-to-front order.

6. A method for preparing the internally opposite-side series-connected perovskite solar cell module of claim 2, comprising:
preparing the front electrode layer on the substrate, scribing the P1 line at a position of each cell unit on the front electrode layer, the P1 line scribing off the front electrode layer and exposing the substrate at the bottom of the groove formed by the P1 line;
laying the light-absorbing layer on the front electrode layer and in the groove formed by the P1 line, scribing the P2 line at a position of the light-absorbing layer close to the P1 line, and the P2 line scribing off the light-absorbing layer and exposing the front electrode layer at the bottom of the groove formed by the P2 line;
laying the back electrode layer on the light-absorbing layer and in the groove formed by the P2 line, scribing the P3 line at a position of the back electrode layer close to the P2 line, and the P3 line scribing off the back electrode layer and light-absorbing layer, exposing the front electrode layer at the bottom of the groove formed by the P3 line, and obtaining the sub-cell pack composed of a positive electrode tab, a negative electrode tab, and a plurality of cell units that are arranged horizontally;
scribing a P4 line at a position of the insulation groove on the back electrode layer, and the P4 line exposing the substrate at a bottom of the insulation groove and retaining a position of the series connection strap on the back electrode layer;
isolating edges around a region where the sub-cell pack is located to expose the substrate at a bottom of the isolated region, and obtaining a plurality of sub-cell packs that are arranged horizontally and sequentially series-connected through the series connection strap, with positions of positive polarities and negative polarities of two adjacent sub-cell packs being same; and
conductively laying the positive electrode busbar on the surface of the back electrode layer of the positive electrode tab of the leftmost sub-cell pack, and conductively laying the negative electrode busbar on the surface of the back electrode layer of the negative electrode tab of the rightmost sub-cell pack, and the positive electrode busbar and the negative electrode busbar being both located on the front side and the rear side of the perovskite solar cell module, respectively.

7. The method for preparing the internally opposite-side series-connected perovskite solar cell module of claim 6, wherein in two adjacent sub-cell packs, the P1 line, the P2 line, and the P3 line in each of the two adjacent sub-cell packs are arranged in a same order.

8. A method for preparing the internally series-connected perovskite solar cell module of claim 3, comprising:
preparing the front electrode layer on the substrate, scribing the P1 line at the position of each cell unit on the front electrode layer, the P1 line scribing off the front electrode layer and exposing the substrate at the bottom of the groove formed by the P1 line;
laying the light-absorbing layer on the front electrode layer and in the groove formed by the P1 line, scribing the P2 line on the light-absorbing layer close to the P1 line, and the P2 line scribing off the light-absorbing layer and exposing the front electrode layer at the bottom of the groove formed by the P2 line;
laying the back electrode layer on the light-absorbing layer and in the groove formed by the P2 line, scribing the P3 line on the back electrode layer close to the P2 line, the P3 line scribing off the back electrode layer and light-absorbing layer exposing the front electrode layer at the bottom of the groove formed by the P3 line, and obtaining the sub-cell pack composed of a positive electrode tab, a negative electrode tab, and a plurality of cell units that are arranged horizontally;
dividing the back electrode layer into a region of internally same-side series-connected perovskite solar cell module and a region of internally opposite-side series-connected perovskite solar cell module,
scribing a P4 line at a position of an intermediate insulation strap on a back electrode layer in the region of internally same-side series-connected perovskite solar cell module, and the P4 line exposing the substrate at a bottom of the intermediate insulation strap, and retaining a position of the intermediate connection strap on the back electrode layer; isolating edges around a region where the sub-cell pack is located to expose the substrate at a bottom of the isolated region, and obtaining a plurality of sub-cell packs that are arranged horizontally and sequentially series-connected through the intermediate connection strap, with positions of positive polarities and negative polarities of two adjacent sub-cell packs being reversed; and
scribing a P4′ line at a position of an insulation groove on a back electrode layer in the region of internally opposite-side series-connected perovskite solar cell module, the P4′ line exposing the substrate at a bottom of the insulation groove, and retaining a position of the series connection strap on the back electrode layer; isolating edges around a region where the sub-cell pack is located to expose the substrate at a bottom of the isolated region, and obtaining a plurality of sub-cell packs that are arranged horizontally and sequentially series-connected through the series connection strap, with positions of positive polarities and negative polarities of two adjacent sub-cell packs being same; and
connecting a prepared internally same-side series-connected perovskite solar cell module and a prepared internally opposite-side series-connected perovskite solar cell module as needed, and conductively laying the positive electrode busbar on a surface of a back electrode layer of a positive electrode tab of one of the sub-cell pack, and conductively laying the negative electrode busbar on a surface of a back electrode layer of a negative electrode tab of another sub-cell pack.
